(19) United States
(12) Patent Application Publication
(10) Pub. No.: US 2023/0163047 A1
(43) Pub. Date: May 25, 2023

(54) FLUID CONDUIT WITHIN A PACKAGE SUBSTRATE FOR TWO-PHASE IMMERSION COOLING SYSTEMS

(71) Applicant: Intel Corporation, Santa Clara, CA (US)

(72) Inventor: Brandon C. Marin, Gilbert, AZ (US)

(73) Assignee: Intel Corporation, Santa Clara, CA (US)

(21) Appl. No.: 17/531,459

(22) Filed: Nov. 19, 2021

(51) Int. Cl. H01L 23/427

(52) U.S. Cl. CPC H01L 23/4275

(57) ABSTRACT

A package substrate, upon which integrated circuit device(s) of an integrated circuit assembly are electrically attached, may include at least one internal fluid conduit that allows for a heat transfer fluid of the two-phase immersion system to transfer heat within the integrated circuit assembly. The at least one internal fluid conduit may comprise at least one fluid channel formed within the package substrate and at least one fluid port extending from an external surface of the package substrate to the at least one fluid channel. The at least one fluid channel may be formed within the package substrate during the formation thereof, then, after the formation of the package substrate, the fluid channels may be “opened” by forming the at least one fluid port.

### TECHNICAL FIELD

Embodiments of the present description generally relate to the field of thermal management for integrated circuit devices, and, more specifically, to two-phase immersion cooling of integrated circuit device(s), wherein the cooling is enhanced with at least one internal fluid conduit extending through a package substrate to which the integrated circuit device(s) are electrically attached.

### BACKGROUND

The integrated circuit industry is continually striving to produce ever faster, smaller, and thinner integrated circuit devices and packages for use in various electronic products, including, but not limited to, computer servers and portable products, such as portable computers, electronic tablets, cellular phones, digital cameras, and the like.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. Thus, heat dissipation devices are used to remove heat from the integrated circuit devices in an integrated circuit package. In one example, heat spreading and dissipation devices may be thermally attached to the integrated circuit devices for heat removal. The heat spreading and dissipation devices, in turn, dissipate the heat into the surrounding atmosphere. In another example, a cooling device, such as a heat exchanger or a heat pipe, may be thermally attached to integrated circuit devices for heat removal. In still another example, integrated circuit devices and/or packages may be immersed in a liquid, wherein heat is dissipated into the liquid without the liquid changing phases (e.g., single phase cooling). However, as power densities and power envelopes increase to reach peak performance, these methods are becoming ineffective in removing sufficient heat.

One emerging heat removal technique is two-phase immersion cooling. This technique essentially comprises immersing an integrated circuit assembly into a liquid cooling bath containing a heat transfer fluid which vaporizes and, thus, cooling the integrated circuit assembly through latent heat transfer, as it generates heat. Although it is a promising technology, two-phase immersion cooling has various challenges to achieve effective operation, as will be understood to those skilled in the art.

For example, in one embodiment of a two-phase immersion cooling assembly, a support substrate, such as a copper block, having a first surface and an opposing second surface, may have a boiling enhancement coating on the first surface and may have the second surface in thermal contact with the heat dissipation device by a thermal interface material layer, such as an indium/aluminum foil. In another example of an embodiment of a two-phase immersion cooling assembly, a boiling enhancement structure, such as a multi-layer copper meshing, may be attached to the heat dissipation device or to the integrated circuit devices directly with a low melting temperature solder. It is noted that two-phase immersion cooling assemblies only dissipate heat from the external surfaces of the integrated circuit packages/devices and/or the heat dissipation devices which contact the heat dissipation fluid thereof. This may restrict the thermal path for cooling the integrated circuit packages/devices, which may result in the two-phase immersion cooling assembly being incapable of removing a sufficient amount of heat.

Thus, there is an on-going effort to improve the operation, efficiency, and cost-effectiveness of two-phase immersion cooling assemblies.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly, according to one embodiment of the present description.

FIG. 2 is a side cross-sectional view of inset A of FIG. 1, according to an embodiment of the present description.

FIGS. 3 and 4 is a side cross-sectional views of internal fluid conduits, according to additional embodiments of the present description.

FIG. 5 is a side cross-sectional view of fluid channels within a package substrate, according to one embodiment of the present description.

FIG. 6 is a side cross-sectional view of fluid channels within a package substrate, according to another embodiment of the present description.

FIG. 7 is a top plan schematic of FIG. 1, according to an embodiment of the present description.

FIG. 8 is a top plan schematic of FIG. 1, according to another embodiment of the present description.

FIG. 9 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description relate to the use of two-phase immersion cooling for integrated circuit assemblies. In one embodiment of the present description, at least one internal fluid conduit may be formed within the package substrate upon which the integrated circuit devices of the integrated circuit assembly are electrically attached. The at least one internal fluid conduit may comprise at least one fluid channel formed within the package substrate and at least one fluid port extending from at least one external surface of the package substrate to the at least one fluid channel. The at least one internal fluid conduit may allow for the heat transfer fluid of the two-phase immersion system to transfer heat within the integrated circuit assembly itself. In an embodiment of the present description, the fluid channels may be formed within the package substrate during the formation thereof, then, after the formation of the package substrate, the fluid channels may be “opened” by forming at least one fluid port into the package substrate. In one embodiment of the present description, the fluid port may be a through-hole extending from a first surface of the package substrate to an opposing second surface of the package substrate.

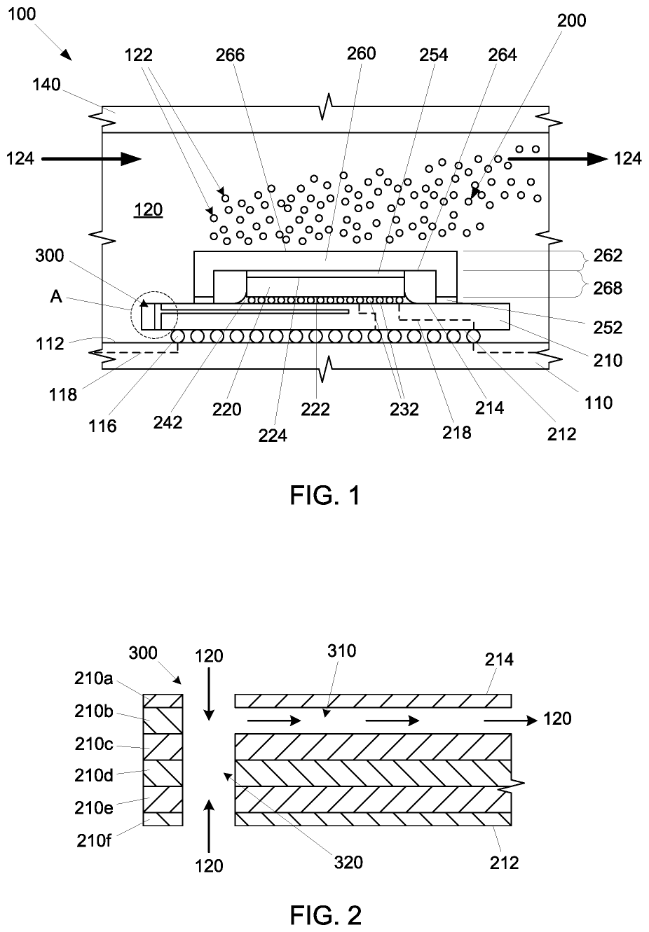

FIG. 1 illustrates an integrated circuit assembly 100 having at least one integrated circuit package 200 electrically attached to an electronic substrate 110. The electronic substrate 110 may be any appropriate structure, including, but not limited to, a motherboard, printed circuit board, and the like. The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 110 may further include conductive routes 118 or “metallization” (shown in dashed lines) extending through the electronic substrate 110. As will be understood to those skilled in the art, the conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 110 may be a cored substrate or a coreless substrate.

The at least one integrated circuit package 200 may be electrically attached to the electronic substrate 110 in a configuration generally known as a flip-chip or controlled collapse chip connection (“C4”) configuration, according to an embodiment of the present description. The integrated circuit package 200 may comprise a package substrate or interposer 210 with a first surface 212 and an opposing second surface 214, and an integrated circuit device 220 electrically attached proximate the second surface 214 of the package substrate 210. In an embodiment of the present description, the package substrate 210 may be attached to the electronic substrate or board 110 with a plurality of package-to-substrate interconnects 116. In one embodiment of the present description, the package-to-substrate interconnects 116 may extend between bond pads (not shown) proximate a first surface 112 of the electronic substrate 110 and bond pads (not shown) proximate the first surface 212 of the package substrate 210. Although not specifically illustrated, it is understood that any appropriate number of integrated circuit devices may be mounted on the package substrate 210.

The package substrate 210 may comprise any of the materials and/or structures as discussed previously with regard to the electronic substrate 110. The package substrate 210 may further include conductive routes 218 or “metallization” (shown in dashed lines) extending through the package substrate 210, which may comprise any of the materials and/or structures as discussed previously with regard to the conductive routes 118 of the electronic substrate 110. Bond pads (not shown) proximate the first surface 212 of the package substrate 210 may be in electrical contact with the conductive routes 218, and the conductive routes 218 may extend through the package substrate 210 and be electrically connected to bond pads (not shown) proximate the second surface 214 of the package substrate 210. As will be understood to those skilled in the art, the package substrate 210 may be a cored substrate or a coreless substrate.

The integrated circuit device 220 may be any appropriate device, including, but not limited to, a microprocessor, a chipset, a graphics device, a wireless device, a memory device, an application specific integrated circuit, a transceiver device, an input/output device, combinations thereof, stacks thereof, and the like. As shown in FIG. 1, the integrated circuit device 220 may have a first surface 222 and an opposing second surface 224. It is understood that, although only a single integrated circuit device 220 is illustrated, any appropriate number of integrated circuit devices may be electrically attached to the package substrate 210.

In an embodiment of the present description, the integrated circuit device 220 may be electrically attached to the package substrate 210 with a plurality of device-to-substrate interconnects 232. In one embodiment of the present description, the device-to-substrate interconnects 232 may extend between bond pads (not shown) on the second surface 214 of the package substrate 210 and bond pads (not shown) on the first surface 222 of the integrated circuit device 220. The device-to-substrate interconnects 232 may be any appropriate electrically conductive material or structure, including, but not limited to, solder balls, metal bumps or pillars, metal filled epoxies, or a combination thereof. In one embodiment of the present description, the device-to-substrate interconnects 232 may be solder balls formed from tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). In another embodiment of the present description, the device-to-substrate interconnects 232 may be copper bumps or pillars. In a further embodiment of the present description, the device-to-substrate interconnects 232 may be metal bumps or pillars coated with a solder material.

The device-to-substrate interconnects 232 may be in electrical communication with integrated circuitry (not shown) within the integrated circuit device 220 and may be in electrical contact with the conductive routes 218. The conductive routes 218 may extend through the package substrate 210 and be electrically connected to package-to-board interconnects 116. As will be understood to those skilled in the art, the package substrate 210 may reroute a fine pitch (center-to-center distance) of the device-to-interposer interconnects 232 to a relatively wider pitch of the package-to-substrate interconnects 116. The package-to-substrate interconnects 116 may be any appropriate electrically conductive material, including, but not limited to, metal filled epoxies and solders, such as tin, lead/tin alloys (for example, 63% tin/37% lead solder), and high tin content alloys (e.g., 90% or more tin—such as tin/bismuth, eutectic tin/silver, ternary tin/silver/copper, eutectic tin/copper, and similar alloys). Although FIG. 1 shows the integrated circuit package 200 attached to the electronic substrate 110 with an interconnect-type attachment, the embodiments of the present description are not so limited. For example, the integrated circuit package 200 may be attached to a socket (not shown) that is electrically attached to the first surface 112 of the electronic substrate 110.

As further shown in FIG. 1, the integrated circuit package 200 may further include a heat dissipation device 260. The heat dissipation device 260 may include, but is not limited to, an integrated heat spreader (shown), a heat dissipation plate, or any such thermally conductive device, that may be thermally coupled with the second surface 224 of the integrated circuit device 220 with an internal thermal interface material 254. The heat dissipation device 260 may comprise a main body 262, having a first surface 264, an opposing second surface 266, at least one sidewall 268, and at least one boundary wall 272 extending from the first surface 264 of the main body 262 of the heat dissipation device 260. The at least one boundary wall 272 may be attached or sealed to the first surface 212 of the package substrate 210 with an attachment adhesive or sealant layer 252.

The heat dissipation device 260 may be made of any appropriate thermally conductive material, including, but not limited to, at least one metal material and alloys of more than one metal, or highly doped glass or highly conductive ceramic material, such as aluminum nitride. In an embodiment of the present description, the heat dissipation device 260 may comprise copper, nickel, aluminum, alloys thereof, laminated metals including coated materials (such as nickel coated copper), and the like. The internal thermal interface material 254 may be any appropriate, thermally conductive material, including, but not limited to, a thermal grease, a thermal gap pad, a polymer, an epoxy filled with high thermal conductivity fillers (such as metal particles or silicon particles), a metal alloy (such as solder or liquid metal), and the like.

As illustrated in FIG. 1, the heat dissipation device 260 may be a single material throughout, such as when the heat dissipation device 260, including the heat dissipation device boundary wall 272, is formed by a single process step, including but not limited to, stamping, skiving, molding, and the like. However, embodiments of the present description may also include the heat dissipation device 260 being made of more than one component. For example, the heat dissipation device boundary wall 272 may be formed separately from the main body 262, then attached together to form the heat dissipation device 260. In one embodiment of the present description, the boundary wall 272 may be a single “picture frame” structure surrounding the integrated circuit device 220.

The attachment adhesive 252 may be any appropriate material, including, but not limited to, silicones (such as polydimethylsiloxane), epoxies, and the like. It is understood that the boundary wall 272 not only secures the heat dissipation device 260 to the package substrate 210, but also helps to maintain a desired distance (e.g., bond line thickness) between the first surface 264 of the heat dissipation device 260 and the second surface 224 of the integrated circuit device 220.

Prior to the attachment of the heat dissipation device 260, an electrically-insulating underfill material 242 may be disposed between the integrated circuit device 220 and the package substrate 210, which substantially encapsulates the device-to-interposer interconnects 232. The underfill material 242 may be used to reduce mechanical stress issues that can arise from thermal expansion mismatch between the package substrate 210 and the integrated circuit device 220. The underfill material 242 may be an appropriate material, including, but not limited to epoxy, cyanoester, silicone, siloxane and phenolic based resins, that has sufficiently low viscosity to be wicked between the integrated circuit device 220 and the package substrate 210 by capillary action when introduced by an underfill material dispenser (not shown), which will be understood to those skilled in the art. The underfill material 242 may be subsequently cured (hardened), such as by heat or radiation.

As shown in FIG. 1, the integrated circuit assembly 100 may further include a heat transfer fluid 120, such as a dielectric low-boiling point liquid, in contact with the integrated circuit package 200. As illustrated, the heat transfer fluid 120 may vaporize (shown in vapor or gas state as bubbles 122) proximate the heat dissipation device 260. In an embodiment of the present description, the heat transfer fluid may be a liquid having a boiling point lower than about 60 degrees Celsius. In one embodiment of the present description, the heat transfer fluid 120 may comprise a fluorocarbon-based fluid. In an embodiment of the present description, the heat transfer fluid 120 may comprise fluorochamicals, including, but not limited to, perfluorohexane, perfluorocarbon, fluoroketone, hydrofluoroether (HFE), hydrofluorocarbon (HFC), hydrofluoroolefin (HFO), and the like. In another embodiment of the present description, the heat transfer fluid 120 may comprise a perfluoroalkylmorpholine, such as 2,2,3,3,5,5,6,6-octafluoro-4-(trifluoromethyl)morpholine. As further shown in FIG. 1, the heat transfer fluid 120 may flow (shown by arrows 124) between the electronic substrate 110 and an adjacent electronic substrate or fluid containment structure 140.

As shown in FIGS. 1 and 2, the package substrate 210 of the integrated circuit assembly 100 may further include at least one internal fluid conduit 300, wherein the internal fluid conduit 300 includes at least one fluid port 320 and at least one fluid channel 310. The at least one internal fluid conduit 300 may allow for the heat transfer fluid 120 to transfer heat within the integrated circuit package 200 itself.

As illustrated in FIG. 2, in one embodiment, the package substrate 210 may comprise a plurality of dielectric material layers (illustrated as elements 210a-210f). The potential materials of these dielectric material layers 210a-210f has been previously discussed. It is noted, that in one embodiment, the outermost layers, i.e., elements 210a and 210f, may be solder resist materials, to contain solder-type interconnects, i.e., the device-to-substrate interconnects 232 and the package-to-substrate interconnects 116, respectively, as will be understood to those skilled in the art.

In an embodiment of the present description, as shown in FIG. 2, the fluid channel 310 may be formed in a dielectric material layer (shown as element 210b) close to the second surface 214 of the package substrate 210, which places it close to the integrated circuit device 220 (see FIG. 1) that generates heat, for optimal heat removal. In one embodiment of the present description, the heat transfer fluid 120 may change phase, e.g., boil, within the internal fluid conduit 300. In another embodiment of the present description, the heat transfer fluid 120 may not change phase within the internal fluid conduit 300, and may merely transfer heat by conduction.

In an embodiment of the present description, the at least one fluid channel 310 may be formed within the package substrate 210 during the formation thereof, then, after the formation of the package substrate 210, the fluid channels 310 may be “opened” by forming the at least one fluid port 320 into the package substrate 210. In one embodiment of the present description, the fluid port 320 may be a through-hole extending from the first surface 212 of the package substrate 210 to the opposing second surface 214 of the package substrate 210. It is understood that through-holes may be formed through the package substrate 210 for the alignment of the integrated circuit package 200 when a socket (not shown) is used for electrical attachment to the electronic substrate 110. Thus, the fluid port 320 may be formed in the same step with the same equipment. The fluid port 320 may be made by any process known in the art, including, but not limited to, drilling, etch, ablating, or the like.

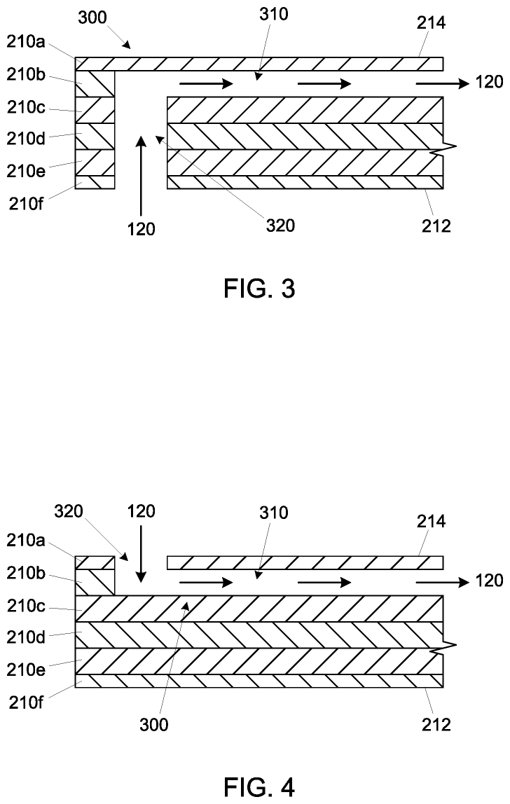

In still another embodiment of the present description, the at least one fluid channel 310 may be formed within the package substrate 210 during the formation thereof, then, after the formation of the package substrate 210, the fluid channels 310 may be “opened” by forming the at least one fluid port 320 into the package substrate 210, but only partially through the package substrate 210, i.e. extending from the first surface 212 of the package substrate 210 to the at least one fluid channel 310, as shown in FIG. 3, or extending from the second surface 214 of the package substrate 210 to the at least one fluid channel 310, as shown in FIG. 4.

In another embodiment of the present description, the at least one fluid channel 310 and the at least one fluid port 320 may be formed within the package substrate 210 during the formation thereof, wherein at least one fluid port 320 only extends partially through the package substrate 210, i.e. extending from the first surface 212 of the package substrate 210 to the at least one fluid channel 310, as shown in FIG. 3, or extending from the second surface 214 of the package substrate 210 to the at least one fluid channel 310, as shown in FIG. 4.

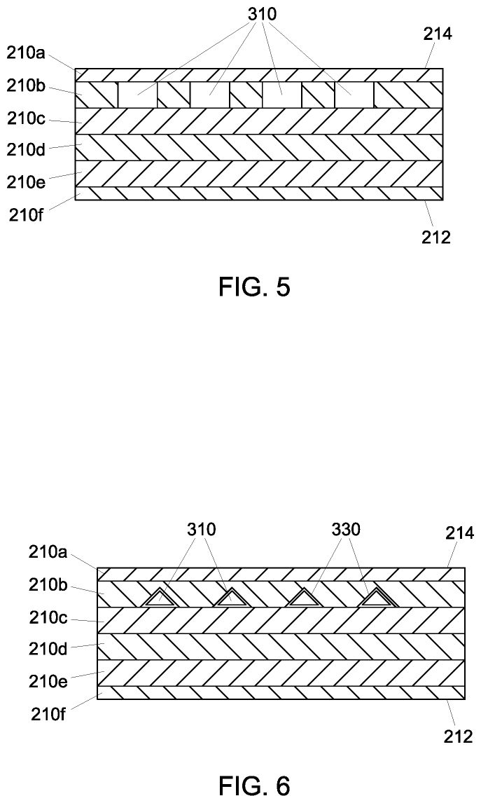

As shown in FIGS. 5 and 6, the fluid channel 310 may have any appropriate cross-section space. In one embodiment of the present description, as shown in FIG. 5, the fluid channels 310 may be substantially rectangular (shown as squares) in cross section. In another embodiment of the present description, as shown in FIG. 6, the fluid channels 310 may be substantially triangular in cross section. It is understood that a substantially triangular fluid channel 310 will be structurally stronger than other configurations. Such a triangular fluid channel 310 may be fabricated using angular etching techniques, such as those used in the formation of waveguides, as will be understood to those skilled in the art.

As further shown in FIG. 6, the fluid channels 310 may be lined with a coating layer 330. In one embodiment, the coating layer 330 may be a structural enhancement layer to prevent the at least one fluid channel 310 from collapsing. In such embodiments, the coating layer 330 may comprise metals, ceramics and the like. In another embodiment, the coating layer 330 may be a barrier material to prevent the heat transfer fluid 120 (see FIGS. 1-4) from contaminating or reacting with the dielectric material layers 210a-210f of the package substrate 210, or vice versa. In such embodiments, the coating layer 330 may comprise metals, metal nitrides, inorganic nitrides, ceramics and the like. In still another embodiment of the present description, the coating layer 330 may be a boiling enhancement material layer, such as a micro-porous coating or a coating of dispersed metal powder/particles. As will be understood to those skilled in the art, the micro-porous coating and the dispersed metal powder/particle coating may provide capillarity for fluid travel of the heat transfer fluid 120 and provide enhanced nucleation sites.

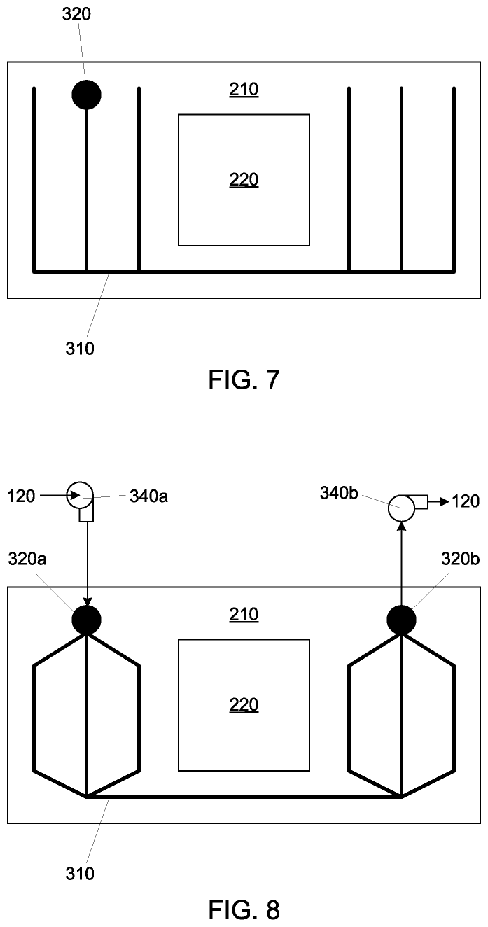

As shown in FIGS. 7 and 8 (illustrating only package substrate 210, the integrated circuit device 220, and the internal fluid conduit 300 for clarity), the fluid channel 310 may have any appropriate routing configuration. As shown in FIG. 7, the fluid channel 310 may be routed within the package substrate 210 with a plurality of corridors. In one embodiment of the present description, as shown in FIG. 5, the fluid channel 310 may be routed to avoid the area closest to the integrated circuit device 220, in order to minimize interference with the conductive routes 218 (see FIG. 1) extending through the package substrate 210, as previously discussed.

As shown in FIG. 8, the fluid channel 310 may fan-out from a first fluid port (labeled as element 320a), e.g., an inlet port, and converge at a second fluid port (labeled as element 320b), e.g., an outlet port, such that the heat transfer fluid 120 (schematically shown as arrows) may enter the first fluid port 320a and exit the second fluid port 320b. In one embodiment, an inlet pump 340a may be used to push the heat transfer fluid 120 through the fluid channel 310. In another embodiment, an outlet pump 340b may be used to pull the heat transfer fluid 120 through the fluid channel 310. The still another embodiment, both the inlet pump 340a and the outlet pump 340b may be used to push and pull the heat transfer fluid 120 through the fluid channel 310.

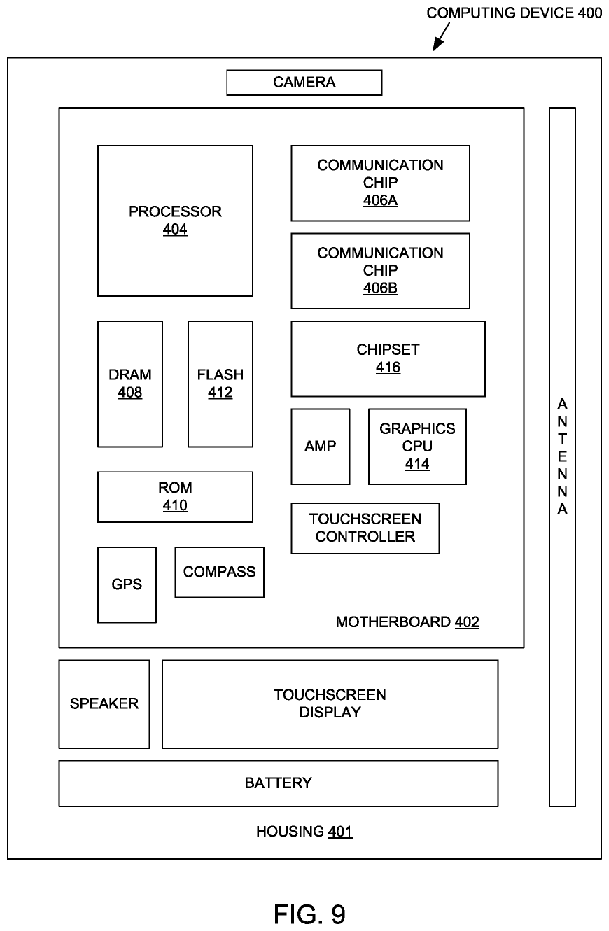

FIG. 9 illustrates an electronic or computing device/system 400 in accordance with one implementation of the present description. The computing device 400 may include a housing 401 having a board 402 disposed therein. The computing device 400 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

The entire computing device 400 or at least one of the integrated circuit components within the computing device 400 may be immersed in a two-phase immersion system. In one embodiment, the integrated circuit component may comprise an integrated circuit package including a substrate having a first surface and an opposing second surface; and an integrated circuit device electrically attached with first surface of the substrate; wherein the substrate includes at least one internal fluid conduit therein, wherein the at least one internal fluid conduit comprises at least one fluid channel within the substrate and at least one fluid port extending to the at least one fluid channel from at least one of the first surface of the substrate and the second surface of the substrate.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-9. The subject matter may be applied to various heat dissipation assemblies, other integrated circuit devices and assembly applications, as well as any appropriate electronic application, as will be understood to those skilled in the art.

The following examples pertain to further embodiments and specifics in the examples may be used anywhere in one or more embodiments, wherein Example 1 is an apparatus, comprising a substrate having a first surface and an opposing second surface; and at least one internal fluid conduit within the substrate, wherein the at least one internal fluid conduit comprises at least one fluid channel within the substrate and at least one fluid port extending to the at least one fluid channel from at least one of the first surface of the substrate and the second surface of the structure.

In Example 2, the subject matter of Example 1 can optionally include the at least one fluid port extending from the first surface of the substrate to the second surface of the substrate.

In Example 3, the subject matter of Example 1 can optionally include a coating layer within the at least one fluid channel.

In Example 4, the subject matter of Example 3 can optionally include the coating layer comprising a structural enhancement layer.

In Example 5, the subject matter of Example 3 can optionally include the coating layer comprising a barrier material.

In Example 6, the subject matter of Example 3 can optionally include the coating layer comprising a boiling enhancement material layer.

Example 7 is an apparatus, comprising a substrate having a first surface and an opposing second surface; and an integrated circuit device electrically attached to a first surface of the substrate, wherein the substrate includes at least one internal fluid conduit within the substrate, wherein the at least one internal fluid conduit comprises at least one fluid channel within the substrate and at least one fluid port extending to the at least one fluid channel from at least one of the first surface of the substrate and the second surface of the structure.

In Example 8, the subject matter of Example 7 can optionally include the at least one fluid port extending from the first surface of the substrate to the second surface of the substrate.

In Example 9, the subject matter of Example 7 can optionally include a coating layer within the at least one fluid channel.

In Example 10, the subject matter of Example 9 can optionally include the coating layer comprising a structural enhancement layer.

In Example 11, the subject matter of Example 9 can optionally include the coating layer comprising a barrier material.

In Example 12, the subject matter of Example 9 can optionally include the coating layer comprising a boiling enhancement material layer.

In Example 13, the subject matter of any of Examples 7 to 12 can optionally include a heat transfer fluid within the internal fluid conduit.

Example 14 is a system, comprising an electronic board and an integrated circuit package electrically attached to the electronic board, wherein the integrated circuit package comprises a substrate having a first surface and an opposing second surface; and an integrated circuit device electrically attached to a first surface of the substrate, wherein the substate includes at least one internal fluid conduit within the substrate, wherein the at least one internal fluid conduit comprises at least one fluid channel within the substrate and at least one fluid port extending to the at least one fluid channel from at least one of the first surface of the substrate and the second surface of the structure.

In Example 15, the subject matter of Example 14 can optionally include the at least one fluid port extending from the first surface of the substrate to the second surface of the substrate.

In Example 16, the subject matter of Example 14 can optionally include a coating layer within the at least one fluid channel.

In Example 17, the subject matter of Example 16 can optionally include the coating layer comprising a structural enhancement layer.

In Example 18, the subject matter of Example 16 can optionally include the coating layer comprising a barrier material.

In Example 19, the subject matter of Example 16 can optionally include the coating layer comprising a boiling enhancement material layer.

In Example 20, the subject matter of any of Examples 14 to 19 can optionally include a heat transfer fluid within the internal fluid conduit.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An apparatus, comprising:
a substrate having a first surface and an opposing second surface; and
at least one internal fluid conduit within the substrate, wherein the at least one internal fluid conduit comprises at least one fluid channel within the substrate and at least one fluid port extending to the at least one fluid channel from at least one of the first surface of the substrate and the second surface of the structure.

2. The apparatus of claim 1, wherein the at least one fluid port extends from the first surface of the substrate to the second surface of the substrate.

3. The apparatus of claim 1, further including a coating layer within the at least one fluid channel.

4. The apparatus of claim 3, wherein the coating layer comprises a structural enhancement layer.

5. The apparatus of claim 3, wherein the coating layer comprises a barrier material.

6. The apparatus of claim 3, wherein the coating layer comprises a boiling enhancement material layer.

7. An apparatus, comprising:
a substrate having a first surface and an opposing second surface; and
an integrated circuit device electrically attached to the first surface of the substrate;
wherein the substrate includes at least one internal fluid conduit therein, wherein the at least one internal fluid conduit comprises at least one fluid channel within the substrate and at least one fluid port extending to the at least one fluid channel from at least one of the first surface of the substrate and the second surface of the substrate.

8. The apparatus of claim 7, wherein the at least one fluid port extends from the first surface of the substrate to the second surface of the substrate.

9. The apparatus of claim 7, further including a coating layer within the at least one fluid channel.

10. The apparatus of claim 9, wherein the coating layer comprises a structural enhancement layer.

11. The apparatus of claim 9, wherein the coating layer comprises a barrier material.

12. The apparatus of claim 9, wherein the coating layer comprises a boiling enhancement material layer.

13. The apparatus of claim 7, further comprising a heat transfer fluid within the internal fluid conduit.

14. A system, comprising:
an electronic board; and
an integrated circuit package electrically attached to the electronic board, wherein the integrated circuit package comprises:
a substrate having a first surface and an opposing second surface; and
an integrated circuit device electrically attached to the first surface of the substrate;
wherein the substrate includes at least one internal fluid conduit therein, wherein the at least one internal fluid conduit comprises at least one fluid channel within the substrate and at least one fluid port extending to the at least one fluid channel from at least one of the first surface of the substrate and the second surface of the substrate.

15. The apparatus of claim 14, wherein the at least one fluid port extends from the first surface of the substrate to the second surface of the substrate.

16. The apparatus of claim 14, further including a coating layer within the at least one fluid channel.

17. The apparatus of claim 16, wherein the coating layer comprises a structural enhancement layer.

18. The apparatus of claim 16, wherein the coating layer comprises a barrier material.

19. The apparatus of claim 16, wherein the coating layer comprises a boiling enhancement material layer.

20. The apparatus of claim 14, further comprising a heat transfer fluid within the internal fluid conduit.
